(19) United States
(12) Patent Application Publication
(10) Pub. No.: US 2025/0277087 A1
(43) Pub. Date: Sep. 4, 2025

(54) MALEIMIDE RESIN, RESIN COMPOSITION, CURED PRODUCT, SHEET, LAMINATE, AND PRINTED WIRING BOARD

(71) Applicant: Resonac Corporation, Tokyo (JP)

(72) Inventors: Tetsuya IMAI, Minato-ku, Tokyo (JP); Kitaru SATO, Minato-ku, Tokyo (JP)

(21) Appl. No.: 18/859,741

(22) PCT Filed: Jul. 19, 2023
(86) PCT No.: PCT/JP2023/026417

§ 371 Date: Oct. 24, 2024

(30) Foreign Application Priority Data
Jul. 22, 2022 (JP) 2022-116958
Sep. 8, 2022 (JP) 2022-142995

(51) Int. Cl. C08G 73/12; C08K 5/14

(52) U.S. Cl. CPC C08G 73/128; C08G 73/121; C08K 5/14

(57) ABSTRACT

A maleimide resin according to the present invention is formed by reacting a tetracarboxylic acid dianhydride (a1), an amine (a2), and maleic anhydride (a3), the amine (a2) including a dimer diamine and a secondary amine that is not a dimer diamine, and at least one of the tetracarboxylic acid dianhydride (a1) and the amine (a2) including a compound that has a fluorene skeleton.

### TECHNICAL FIELD

The present disclosure relates to a maleimide resin, a resin composition, a cured product, a sheet, a laminate, and a printed wiring board.

### BACKGROUND ART

Printed wiring boards and multilayer wiring boards using the same are used in mobile communication devices such as mobile phones and smartphones, network-related electronic devices such as base station devices, servers, and routers for the mobile communication devices, and products such as large computers.

These days, in these products, high-frequency electric signals are used in order to transmit and process large amounts of information at high speed; however, high-frequency signals are very easily attenuated, and thus an insulating material excellent in dielectric characteristics is required as an insulating material used for the printed wiring boards, the multilayer wiring boards, etc. in order to suppress transmission loss.

As the insulating material, epoxy resin compositions disclosed in Patent Literatures 1 to 3 are known. Patent Literature 1 discloses that an epoxy resin composition containing an epoxy resin, an active ester compound, and a triazine-containing cresol novolac resin is effective to reduce the dielectric loss tangent. Patent Literatures 2 and 3 disclose that a resin composition containing an epoxy resin and an active ester compound as essential components can form a cured product having a low dielectric loss tangent and is useful as an insulating material. However, it has been becoming clear that these epoxy resin compositions are not satisfactory as ones for high-frequency band uses.

On the other hand, Patent Literature 4 reports that a resin film formed of, as a non-epoxy-based material, a resin composition containing a bismaleimide resin having a long-chain alkyl group and a curing agent is excellent in dielectric characteristics (has a low relative permittivity and a low dielectric loss tangent). However, a bismaleimide resin made only of a long-chain alkyldiamine has had problems of a low Tg and a low elastic modulus.

### CITATION LIST

### Patent Literature

Patent Literature 1: Japanese Unexamined Patent Publication No. 2011-132507
Patent Literature 2: Japanese Unexamined Patent Publication No. 2015-101626
Patent Literature 3: Japanese Unexamined Patent Publication No. 2017-210527
Patent Literature 4: WO 2016/114287 A

### SUMMARY OF INVENTION

### Technical Problem

An object of the present disclosure is to provide a novel maleimide resin. An object of the present disclosure is to provide a maleimide resin capable of forming a cured product having an increased elastic modulus and an increased Tg while sufficiently maintaining a low permittivity and a low dielectric loss tangent. Another object of the present disclosure is to provide a resin composition, a cured product, a sheet, a laminate, and a printed wiring board using the maleimide resin.

### Solution to Problem

As a result of extensive studies to solve the above problems, the present inventors have found that a cured product having an increased elastic modulus and an increased Tg while sufficiently maintaining a low permittivity and a low dielectric loss tangent can be formed by using a maleimide resin obtained by reacting a tetracarboxylic dianhydride (a1), an amine (a2), and maleic anhydride (a3), in which the amine (a2) contains a dimer diamine and a second amine other than the dimer diamine, and at least one of the tetracarboxylic dianhydride (a1) and the amine (a2) contains a compound having a fluorene skeleton, and have completed the present invention.

That is, the present disclosure provides the following maleimide resin, resin composition, cured product, sheet, laminate, and printed wiring board.

[1] A maleimide resin obtained by reacting a tetracarboxylic dianhydride (a1), an amine (a2), and maleic anhydride (a3), in which the amine (a2) contains a dimer diamine and a second amine other than the dimer diamine, and at least one of the tetracarboxylic dianhydride (a1) and the amine (a2) contains a compound having a fluorene skeleton.
[2] The maleimide resin according to [1] above, in which the tetracarboxylic dianhydride (a1) contains at least one of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 9,9-bis[4-(3,4-dicarboxyphenoxy)phenyl]fluorene dianhydride, and 3,3′,4,4′-biphenyltetracarboxylic dianhydride.
[3] The maleimide resin according to [1] or [2] above, in which the second amine contains at least one of norbornanediamine, 9,9-bis[4-(4-aminophenoxy)phenyl]fluorene, and 9,9-bis(4-aminophenyl)fluorene.
[4] The maleimide resin according to any one of [1] to [3] above, in which the dimer diamine contains at least one of compounds represented by General Formula (1) below and compounds represented by General Formula (2) below,

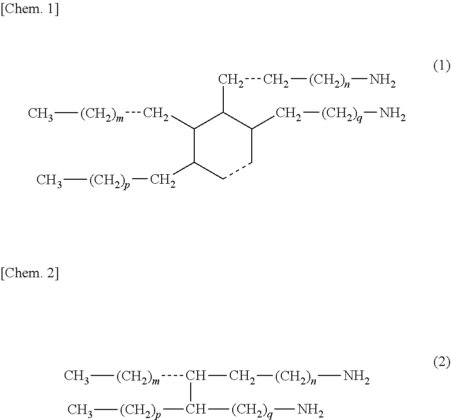

in which m, n, p, and q each represent an integer of 1 or more selected such that m+n=6 to 17 and p+q=8 to 19, and a bond indicated by a broken line represents a carbon-carbon single bond or a carbon-carbon double bond, provided that, when the bond indicated by the broken line is a carbon-carbon double bond, each of Formulae (1) and (2) has a structure in which the number of hydrogen atoms bonded to each carbon atom forming the carbon-carbon double bond is a number obtained by subtracting 1 from the number shown in the respective one of Formulae (1) and (2).
   [5] The maleimide resin according to any one of [1] to [4] above, in which the weight average molecular weight is 3000 to 30000. [6] The maleimide resin according to any one of [1] to [5] above, obtained by reacting 0.30 to 1.00 mol of the tetracarboxylic dianhydride (a1) with 1 mol of the amine (a2).
   [7] A resin composition containing the maleimide resin (A) according to any one of [1] to [6] above.
   [8] The resin composition according to [7] above, further containing a polymerization initiator (B).
   [9] A cured product of the resin composition according to [7] or [8] above.
   [10] A sheet including: the resin composition according to [7] or [8] above; and a base material.
   [11] The sheet according to [10] above, in which the base material is an organic base material.
   [12] The sheet according to [10] above, in which the base material is an inorganic base material.
   [13] A laminate obtained by thermocompression-bonding a base material to an adhesive surface of the sheet according to any one of [10] to [12] above.
   [14] A printed wiring board obtained by using the sheet according to any one of [10] to [12] above.
   [15] A printed wiring board obtained by using the laminate according to [13] above.

### Advantageous Effects of Invention

According to the present disclosure, a maleimide resin capable of forming a cured product having an increased elastic modulus and an increased Tg while sufficiently maintaining a low permittivity and a low dielectric loss tangent can be provided. The present disclosure can also provide a resin composition, a cured product, a sheet, a laminate, and a printed wiring board using the maleimide resin.

The maleimide resin and the resin composition (adhesive composition) using the same of the present disclosure can reduce both the permittivity and the dielectric loss tangent (hereinafter, both may be collectively referred to as “dielectric characteristics”), and are particularly excellent in low dielectric characteristics in a high frequency band. Further, since the cured product (adhesive layer) obtained from the resin composition has a high elastic modulus and a high Tg, the resin composition is useful not only as adhesives used for manufacturing printed circuit boards (build-up substrates, flexible printed wiring boards, and the like) and copper clad boards for printed wiring boards, but also as semiconductor interlayer materials, coating agents, resist inks, conductive pastes, and the like.

### DESCRIPTION OF EMBODIMENTS

Hereinbelow, preferred embodiments of the present disclosure are described in detail. However, the present disclosure is not limited to the following embodiments, and can be implemented with various modifications within the scope of the gist of the present disclosure.

In the present specification, a numerical range specified using “to” indicates a range including the numerical values written before and after “to” as a minimum value and a maximum value, respectively. In numerical ranges written in stages in the present specification, the upper limit value or the lower limit value of a numerical range in a certain stage can be arbitrarily combined with the upper limit value or the lower limit value of a numerical range in another stage. In a numerical range written in the present specification, the upper limit value or the lower limit value of the numerical range may be replaced with a value shown in Examples. “A or B” needs only to include either of A and B, and may include both of them. For the materials given as examples in the present specification, one kind can be used singly, or two or more kinds can be used in combination, unless otherwise specified. In the case where in the composition there are a plurality of substances falling under a component, the content amount of the component in the composition means, unless otherwise specified, the total amount of the plurality of substances present in the composition. In the present specification, the “solid content” refers to a nonvolatile content excluding volatile substances (water, solvent, etc.) contained in the resin composition, and includes also a component in the form of a liquid, syrup, or a wax at room temperature (around 25° C.).

### <Maleimide Resin and Resin Composition>

The maleimide resin of the present embodiment is a maleimide resin obtained by reacting a tetracarboxylic dianhydride (a1) (hereinafter, also referred to as an “(a1) component”), an amine (a2) (hereinafter, also referred to as an “(a2) component”), and maleic anhydride (a3) (hereinafter, also referred to as an “(a3) component”). Here, the (a2) component contains a dimer diamine and a second amine other than the dimer diamine. Further, at least one of the (a1) component and the (a2) component contains a compound having a fluorene skeleton.

The resin composition of the present embodiment contains the maleimide resin (A) (hereinafter, also referred to as an “(A) component”). The resin composition of the present embodiment may further contain a polymerization initiator (B) (hereinafter, also referred to as a “(B) component”). The resin composition of the present embodiment may further contain an organic solvent (C) (hereinafter, also referred to as a “(C) component”).

### ((A) Component: Maleimide Resin)

The (A) component can be obtained by reacting the (a1) component, the (a2) component, and the (a3) component. The (A) component may have a plurality of maleimide groups in the molecule. The (A) component may be a bismaleimide resin.

As the tetracarboxylic dianhydride of the (a1) component, those known as source materials of polyimides can be used. Examples of the (a1) component include pyromellitic anhydride, 4,4′-(hexafluoroisopropylidene)diphthalic anhydride, 1,3,3a,4,5,9b-hexahydro-5-(tetrahydro-2,5-dioxo-3-furanyl)naphtho[1,2-C]furan-1,3-dione, 4,4′-oxydiphthalic dianhydride, 3,3′,4,4′-diphenylsulfonetetracarboxylic dianhydride, 3,3′,4,4′-biphenyltetracarboxylic dianhydride, 3,3′,4,4′-benzophenonetetracarboxylic dianhydride, 4,4′-(4,4′-isopropylidenediphenoxy)diphthalic anhydride, 1,2,3,4-butanetetracarboxylic dianhydride, 1,2,3,4-cyclobutanetetracarboxylic dianhydride, 1,2,3,4-cyclopentanetetracarboxylic dianhydride, 1,2,3,4-tetramethyl-1,2,3,4-cyclobutanetetracarboxylic dianhydride, bicyclo[2.2.2]oct-7-ene-2,3,5,6-tetracarboxylic dianhydride, 1,4-phenylene bis(1,3-dioxo-1,3-dihydroisobenzofuran-5-carboxylate), 9,9-bis(3,4-dicarboxyphenyl)fluorene dianhydride, 4,4′-(ethyne-1,2-diyl)diphthalic anhydride, 5-(2,5-dioxotetrahydrofuryl)-3-methyl-3-cyclohexene-1,2-dicarboxylic anhydride, dicyclohexyl-3,4,3′,4′-tetracarboxylic dianhydride, 3,4′-oxydiphthalic anhydride, 3,4′-biphthalic anhydride, norbornane-2-spiro-α-cyclopentanone-α′-spiro-2″-norbornane-5,5″,6,6″-tetracarboxylic dianhydride, 5,5′-bis-2-norbornene-5,5′,6,6′-tetracarboxylic 5,5′,6,6′-dianhydride, 9,9-bis[4-(3,4-dicarboxyphenoxy)phenyl]fluorene dianhydride, and the like. For these, one kind can be used singly, or two or more kinds can be used in combination.

From the viewpoint of low dielectric characteristics, a high Tg, or a low coefficient of linear expansion (CTE), the (a1) component preferably contains at least one selected from the group consisting of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 3,3′,4,4′-biphenyltetracarboxylic dianhydride, 4,4′-(4,4′-isopropylidenediphenoxy)diphthalic anhydride, 4,4′-(hexafluoroisopropylidene)diphthalic anhydride, 5-(2,5-dioxotetrahydrofuryl)-3-methyl-3-cyclohexene-1,2-dicarboxylic anhydride, dicyclohexyl-3,4,3′,4′-tetracarboxylic dianhydride, bicyclo[2.2.2]octane-2,3,5,6-tetracarboxylic 2,3:5,6-dianhydride, 5,5′-bis-2-norbornene-5,5′,6,6′-tetracarboxylic 5,5′,6,6′-dianhydride, 3,4′-biphthalic anhydride, and 9,9-bis[4-(3,4-dicarboxyphenoxy)phenyl]fluorene dianhydride, more preferably contains at least one selected from the group consisting of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 4,4′-(4,4′-isopropylidenediphenoxy)diphthalic anhydride, 4,4′-(hexafluoroisopropylidene)diphthalic anhydride, 9,9-bis[4-(3,4-dicarboxyphenoxy)phenyl]fluorene dianhydride, and 3,3′,4,4′-biphenyltetracarboxylic dianhydride, and still more preferably contains at least one of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 9,9-bis[4-(3,4-dicarboxyphenoxy)phenyl]fluorene dianhydride, and 3,3′,4,4′-biphenyltetracarboxylic dianhydride.

The (a2) component contains a dimer diamine (a first diamine) and a second amine other than the dimer diamine.

The dimer diamine is, for example, a compound derived from a dimer acid that is a dimer of an unsaturated fatty acid such as oleic acid, as described in Japanese Unexamined Patent Publication No. H9-12712. The dielectric characteristics of the cured product can be reduced by using a dimer diamine as the (a2) component. In the present embodiment, known dimer diamines can be used without particular limitation. The dimer diamine preferably contains, for example, at least one of compounds represented by General Formula (1) below and compounds represented by General Formula (2) below,

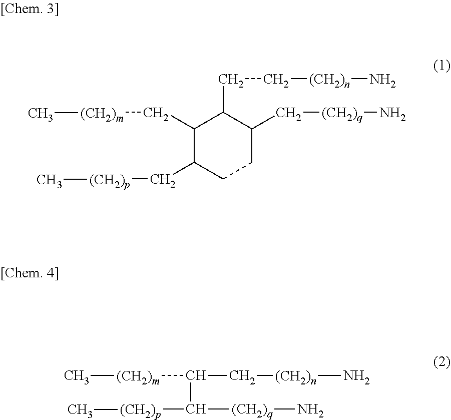

in which m, n, p, and q each represent an integer of 1 or more selected such that m+n=6 to 17 and p+q=8 to 19, and a bond indicated by a broken line represents a carbon-carbon single bond or a carbon-carbon double bond, provided that, when the bond indicated by the broken line is a carbon-carbon double bond, each of Formulae (1) and (2) has a structure in which the number of hydrogen atoms bonded to each carbon atom forming the carbon-carbon double bond is a number obtained by subtracting 1 from the number shown in the respective one of Formulae (1) and (2).

From the viewpoint of solubility in the organic solvent, heat resistance, thermal adhesion resistance, low viscosity, etc., the dimer diamine may be one represented by General Formula (2) above, and may be particularly a compound represented by Formula (3) below.

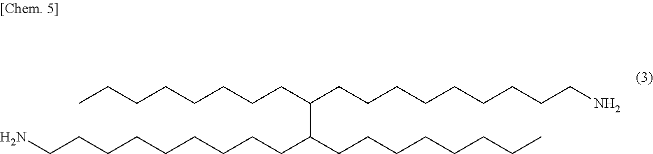

Examples of commercially available products of the dimer diamine include PRIAMINE 1075 and PRIAMINE 1074 (both manufactured by Croda Japan K.K.), and the like. For these, one kind can be used singly, or two or more kinds can be used in combination.

The second amine is an amine not falling under the dimer diamine described above. The second amine may be a diamine or a triamine, and may be a diamine. The permittivity can be reduced more by using an alicyclic diamine as the second amine. The elastic modulus, Tg, and CTE of the cured product are improved by using an aromatic diamine as the second amine.

In the case where the second amine is a diamine, examples of the diamine include 1,3-diaminopropane, norbornanediamine, 4,4-methylenedianiline, 1,3-bis[2-(4-aminophenyl)-2-propyl]benzene, 4,4′-diamino-2,2′-bis(trifluoromethyl)biphenyl, 2,2-bis[4-(4-aminophenoxy)phenyl]hexafluoropropane, 9,9-bis(4-aminophenyl)fluorene, 9,9-bis[3-fluoro-4-aminophenyl]fluorene, 9,9-bis[4-(4-aminophenoxy)phenyl]fluorene, 1,3-bis(aminomethyl)cyclohexane, 1,4-bis(aminomethyl)cyclohexane, bis(aminomethyl)norbornane, 4,4′-(hexafluoroisopropylidene)dianiline, 3(4),8(9)-bis(aminomethyl)tricyclo[5.2.1.02,6]decane, 1,3-cyclohexanediamine, 1,4-cyclohexanediamine, isophoronediamine, 4,4′-methylenebis(cyclohexylamine), 4,4′-methylenebis(2-methylcyclohexylamine), 1,1-bis(4-aminophenyl)cyclohexane, 2,7-diaminofluorene, 4,4′-ethylenedianiline, 4,4′-methylenebis(2,6-diethylaniline), 4,4′-methylenebis(2-ethyl-6-methylaniline), 2,2-bis[4-(4-aminophenoxy)phenyl]propane, bis[4-(4-aninophenoxy)phenyl]methane, 4,4′-bis(4-aminophenoxy)biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, (4,4′-diamino)diphenyl ether, (3,3′-diamino)diphenyl ether, paraphenylenediamine, orthophenylenediamine, metaphenylenediamine, 2,2′-dimethylbiphenyl-4,4′-diamine, bis[4-(3-aminophenoxy)phenyl]sulfone, bis[4-(4-aninophenoxy)phenyl]sulfone, and the like. For these, one kind can be used singly, or two or more kinds can be used in combination.

In the case where the second amine is a triamine, examples of the triamine include tris(2-aminomethyl)amine, tris(2-aminoethyl)amine, tris(2-aminopropyl)amine, 2-(aminomethyl)-2-methyl-1,3-propanediamine, trimer triamines, 3,4,4′-triaminodiphenyl ether, 1,2,4-triaminobenzene, 1,3,5-triaminobenzene, 1,2,3-triaminobenzene, 1,3,5-triazine-2,4,6-triamine, 2,4,6-triaminopyrimidine, 1,3,5-tris(4-aminophenyl)benzene, 1,3,5-tris(4-aminophenoxy)benzene, and the like. For these, one kind can be used singly, or two or more kinds can be used in combination. Among these, aliphatic triamines are preferable from the viewpoint of the solubility of the synthesized (A) component in the organic solvent, and tris(2-aminomethyl)amine and tris(2-aminoethyl)amine, which have small numbers of carbon atoms, are more preferable from the viewpoint of increasing Tg.

The second amine may contain one of the diamine and the triamine described above, or may contain both of them. The second amine may contain an amine other than diamines or triamines.

From the viewpoint of a high Tg, a high elastic modulus, and a low CTE, the second amine preferably contains at least one of norbornanediamine, 9,9-bis[4-(4-aminophenoxy)phenyl]fluorene, and 9,9-bis(4-aminophenyl)fluorene.

In the (a2) component, the molar ratio of the second amine to the total amount of the amines (the number of moles of the second amine/(the number of moles of the dimer diamine+the number of moles of the second amine)) may be 70 mol % or less, or may be 50 mol % or less. When this ratio is 70 mol % or less, the dielectric characteristics of the cured product can be reduced more.

In the case where the second amine contains a diamine, the molar ratio of the diamine in the second amine to the total amount of the diamine in the (a2) component (the number of moles of the diamine in the second amine/(the number of moles of the dimer diamine+the number of moles of the diamine in the second amine)) may be 70 mol % or less, or may be 50 mol % or less. When this ratio is 70 mol % or less, the dielectric characteristics of the cured product can be reduced more.

The dielectric characteristics of the cured product can be reduced by using a dimer diamine as the diamine. On the other hand, in the case where only the dimer diamine is used as the amine, the elastic modulus and Tg of the cured product are reduced. In this regard, by using the second amine, particularly a diamine other than the dimer diamine, in combination with the dimer diamine, the elastic modulus and Tg can be improved while the dielectric characteristics of the cured product are maintained.

At least one of the (a1) component and the (a2) component described above contains a compound having a fluorene skeleton. By virtue of the fact that at least one of the (a1) component and the (a2) component contained in the maleimide resin contains a compound having a fluorene skeleton, the cured product obtained using the maleimide resin is allowed to be one having an increased elastic modulus, an increased Tg, and a reduced CTE while sufficiently maintaining a low permittivity and a low dielectric loss tangent. From the viewpoint of more increasing the elastic modulus and Tg of the cured product and reducing the CTE, both the (a1) component and the (a2) component described above may contain a compound having a fluorene skeleton.

The (A) component can be produced by various known methods. For example, first, the (a1) component and the (a2) component are subjected to polyaddition reaction at a temperature of about 60 to 120° C., preferably 70 to 90° C., for usually about 0.1 to 2 hours, preferably 0.1 to 1.0 hours. Next, the obtained polyadduct is subjected to imidation reaction, that is, a dehydration ring closure reaction at a temperature of about 80 to 250° C., preferably 100 to 200° C., for about 0.5 to 30 hours, preferably 0.5 to 10 hours. Subsequently, the product obtained by the dehydration ring closure reaction and the (a3) component are subjected to maleimidation reaction, that is, a dehydration ring closure reaction, at a temperature of about 60 to 250° C., preferably 80 to 200° C., for about 0.5 to 30 hours, preferably 0.5 to 10 hours, and thereby the (A) component of interest is obtained.

In the imidation reaction or the maleimidation reaction, various known reaction catalysts, dehydrating agents, and organic solvents described later can be used. Examples of the reaction catalyst include aliphatic tertiary amines such as triethylamine, aromatic tertiary amines such as dimethylaniline, heterocyclic tertiary amines such as pyridine, picoline, and isoquinoline, organic acids such as methanesulfonic acid and paratoluenesulfonic acid monohydrate, and the like. For these, one kind can be used singly, or two or more kinds can be used in combination. Examples of the dehydrating agent include aliphatic acid anhydrides such as acetic anhydride, aromatic acid anhydrides such as benzoic anhydride, and the like. For these, one kind can be used singly, or two or more kinds can be used in combination.

The (A) component can be purified by various known methods, and the purity can be increased. For example, first, the (A) component dissolved in an organic solvent and pure water are put into a separating funnel. Next, the separating funnel is shaken, and is allowed to stand still. Subsequently, after the aqueous layer and the organic layer are separated, only the organic layer is collected; thereby, the (A) component can be purified.

An assumed structure of the (A) component produced by the above method is shown in General Formula (4) below. General Formula (4) is one on the assumption that the second amine is a diamine.

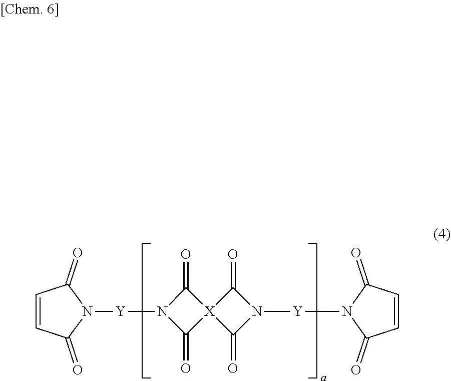

In General Formula (4), X each independently represents a tetravalent organic group, Y each independently represents a divalent organic group, and a represents an integer of 1 or more. However, at least one of the plurality of Y's represents a divalent organic group derived from the dimer diamine described above, and at least one of the plurality of Y's represents a divalent organic group derived from the second amine (diamine) described above. X and Y may each be an aliphatic group, or an organic group having an alicyclic structure or an aromatic ring, and each of these groups may contain a hetero atom. However, at least one of X and Y represents a tetravalent organic group having a fluorene skeleton.

The molecular weight of the (A) component can be controlled by the numbers of moles of the (a1) component and the (a2) component; the molecular weight can be made smaller as the number of moles of the (a1) component becomes smaller relative to the number of moles of the (a2) component. For the purpose of easily achieving the effect of the present disclosure, the number of moles of the (a1) component relative to 1 mole of the (a2) component, that is, [the number of moles of the (a1) component]/[the number of moles of the (a2) component] is usually in the range of about 0.30 to 1.00, preferably 0.30 to 0.95, more preferably 0.30 to 0.90, and still more preferably 0.50 to 0.80.

From the viewpoint of solubility in the solvent and heat resistance, the molecular weight of the (A) component is, in terms of weight average molecular weight (Mw), preferably 3000 to 30000, more preferably 3000 to 25000, still more preferably 5000 to 23000, and particularly preferably 7000 to 20000. There is a tendency that when the weight average molecular weight is 30000 or less, solubility in the organic solvent is improved, and when the weight average molecular weight is 3000 or more, the effect of improving heat resistance is sufficiently obtained.

The Mw can be found by measurement by gel permeation chromatography (GPC) and conversion using a calibration curve of standard polystyrene.

For the (A) component, one kind can be used singly, or two or more kinds can be used in combination.

### ((B) Component: Polymerization Initiator)

As the (B) component, various known polymerization initiators can be used without particular limitation as long as they are ones that can be used in the resin composition. Specific examples of the (B) component include organic peroxides, imidazole compounds, phosphine compounds, phosphonium salt compounds, and the like. For these, one kind can be used singly, or two or more kinds can be used in combination. Among these, particularly organic peroxides and imidazole compounds have excellent functions as polymerization initiators and are excellent also in terms of low dielectric characteristics, and are therefore preferable.

Examples of the organic peroxide include methyl ethyl ketone peroxide, methylcyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl 4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butyl cumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy)hexane, 1,1,3,3-tetramethylbutyl peroxy-2-ethylhexanoate, 1-cyclohexyl-1-methylethyl peroxy-2-ethylhexanoate, t-hexyl peroxy-2-ethylhexanoate, t-butyl peroxy-2-ethylhexanoate, t-butyl peroxyisobutyrate, t-butylperoxymaleic acid, t-butyl peroxylaurate, t-butyl peroxy-3,5,5-trimethylhexanoate, t-butylperoxy isopropyl monocarbonate, t-butylperoxy 2-ethylhexyl monocarbonate, 2,5-dimethyl-2,5-bis(benzoylperoxy)hexane, t-butyl peroxyacetate, t-hexyl peroxybenzoate, t-butyl peroxy-m-toluoylbenzoate, t-butyl peroxybenzoate, bis(t-butylperoxy) isophthalate, t-butylperoxy allyl monocarbonate, 3,3′,4,4′-tetra(t-butylperoxycarbonyl)benzophenone, and the like. For these, one kind can be used singly, or two or more kinds can be used in combination. Among these organic peroxides, dicumyl peroxide, 2,5-dimethyl-2,5-bis(t-butylperoxy)hexane, α,α′-bis(t-butylperoxy)diisopropylbenzene, and the like are preferable.

Examples of the imidazole compound include 2-ethyl-4-methylimidazole, 2-methylimidazole, 2-ethylimidazole, 2,4-dimethylimidazole, 2-undecylimidazole, 2-heptadecylimidazole, 2-phenylimidazole, 2-phenyl-4-methylimidazole, 1-benzyl-2-methylimidazole, 2-phenyl-4,5-dihydroxymethylimidazole, 2-phenyl-4-methyl-5-hydroxymethylimidazole, 1-vinyl-2-methylimidazole, 1-propyl-2-methylimidazole, 2-isopropylimidazole, 1-cyanomethyl-2-methylimidazole, 1-cyanoethyl-2-ethyl-4-methylimidazole, 1-cyanoethyl-2-undecylimidazole, 1-cyanoethyl-2-phenylimidazole, and the like. Among these, 1-cyanoethyl-2-phenylimidazole and 2-ethyl-4-methylimidazole have high solubility with the resin composition of the present embodiment, and are preferable. For these, one kind can be used singly, or two or more kinds can be used in combination.

Examples of the phosphine compound include primary phosphines, secondary phosphines, tertiary phosphines, and the like. Specific examples of the primary phosphine include alkylphosphines such as ethylphosphine and propylphosphine, phenylphosphine, and the like. Specific examples of the secondary phosphine include dialkylphosphines such as dimethylphosphine and diethylphosphine, secondary phosphines such as diphenylphosphine, methylphenylphosphine, and ethylphenylphosphine, and the like. Examples of the tertiary phosphine include trialkylphosphines such as trimethylphosphine, triethylphosphine, tributylphosphine, and trioctylphosphine, tricyclohexylphosphine, triphenylphosphine, alkyldiphenylphosphines, dialkylphenylphosphines, tribenzylphosphine, tritolylphosphine, tri-p-styrylphosphine, tris(2,6-dimethoxyphenyl)phosphine, tri-4-methylphenylphosphine, tri-4-methoxyphenylphosphine, tri-2-cyanoethylphosphine, and the like. Among these, tertiary phosphines are preferably used. For these, one kind can be used singly, or two or more kinds can be used in combination.

Examples of the phosphonium salt compound include a compound having a tetraphenylphosphonium salt, an alkyltriphenylphosphonium salt, a tetraalkylphosphonium, or the like; specific examples include tetraphenylphosphonium thiocyanate, tetraphenylphosphonium tetra-p-methylphenylborate, butyltriphenylphosphonium thiocyanate, tetraphenylphosphonium phthalate, tetrabutylphosphonium 1,2-cyclohexyldicarboxylate, tetrabutylphosphonium 1,2-cyclohexyldicarboxylate, tetrabutylphosphonium laurate, and the like. For these, one kind can be used singly, or two or more kinds can be used in combination.

The content amount of the (B) component is not particularly limited, but is preferably 0.1 to 10.0 parts by mass, more preferably 0.2 to 5.0 parts by mass, still more preferably 0.3 to 3.0 parts by mass, particularly preferably 0.3 to 1.0 parts by mass, and extremely preferably 0.3 to 0.6 parts by mass, relative to 100 parts by mass of the (A) component.

### ((C) Component: Organic Solvent)

The (C) component is not particularly limited as long as it is one that dissolves the (A) component. As the (C) component, for example, aromatic hydrocarbon-based solvents such as benzene, toluene, xylene, mesitylene, and pseudocumene, alcohol-based solvents such as methanol, ethanol, isopropyl alcohol, butanol, pentanol, hexanol, propanediol, and phenol, ketone-based solvents such as acetone, methyl isobutyl ketone, methyl ethyl ketone, pentanone, hexanone, cyclopentanone, cyclohexanone, isophorone, and acetophenone, Cellosolves such as Methyl Cellosolve and Ethyl Cellosolve, ester-based solvents such as methyl acetate, ethyl acetate, butyl acetate, methyl propionate, and butyl formate, glycol ether-based solvents such as ethylene glycol mono-n-butyl ether, ethylene glycol mono-iso-butyl ether, ethylene glycol mono-tert-butyl ether, diethylene glycol mono-n-butyl ether, diethylene glycol mono-iso-butyl ether, triethylene glycol mono-n-butyl ether, and tetraethylene glycol mono-n-butyl ether, amide-based solvents such as N-methyl-2-pyrrolidone, and the like can be used. For these, one kind may be used, or two or more kinds may be used in combination. Among these, an aromatic hydrocarbon-based solvent having high solubility of the (A) component, such as toluene or mesitylene, is preferably used.

The amount of the (C) component used is not particularly limited, but may be usually used in such a range that the nonvolatile content of the resin composition of the present embodiment accounts for about 20 to 65 mass %.

The preparation of the resin composition of the present embodiment is performed according to a generally employed method. Examples of the preparation method include methods such as melt mixing, powder mixing, and solution mixing. At this time, components other than the essential components of the present embodiment, for example a mold release agent, a flame retardant, an ion trapping agent, an antioxidant, an adhesion imparting agent, a low stress agent, a coloring agent, a coupling agent, an inorganic filler, etc., may be blended to the extent that the effect of the present disclosure is not impaired. Further, the resin composition of the present embodiment may contain a resin other than the (A) component, such as an epoxy resin, an acrylate compound, a vinyl compound, a benzoxazine compound, or a bismaleimide compound other than the (A) component.

### (Mold Release Agent)

The mold release agent is added to improve releasability from a mold. As the mold release agent, for example, known ones such as carnauba wax, rice wax, candelilla wax, polyethylene, oxidized polyethylene, polypropylene, montanic acid, montan wax, which is an ester compound of montanic acid and a saturated alcohol, 2-(2-hydroxyethylamino)ethanol, ethylene glycol, glycerin, or the like, stearic acid, stearic acid esters, and stearic acid amides can all be used. For these, one kind can be used singly, or two or more kinds can be used in combination.

### (Flame Retardant)

The flame retardant is added to impart flame retardancy; as the flame retardant, all known ones can be used, and there is no particular limitation. Examples of the flame retardant include phosphazene compounds, silicon compounds, zinc molybdate-supported talc, zinc molybdate-supported zinc oxide, aluminum hydroxide, magnesium hydroxide, molybdenum oxide, and the like. For these, one kind can be used singly, or two or more kinds can be used in combination.

### (Ion Trapping Agent)

The ion trapping agent is added to trap ion impurities contained in the liquid resin composition and to prevent thermal deterioration and moisture absorption deterioration. As the ion trapping agent, all known ones can be used, and there is no particular limitation. Examples of the ion trapping agent include hydrotalcites, bismuth hydroxide compounds, rare earth oxides, and the like. For these, one kind can be used singly, or two or more kinds can be used in combination.

### (Inorganic Filler)

As the inorganic filler, various known inorganic fillers can be used without particular limitation as long as they are ones that can be used in the resin composition. Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, silica, graphite powder, boehmite, and the like. Among these, particularly silica is excellent in low dielectric loss tangent, and is therefore preferable. For the inorganic filler, one kind can be used singly, or two or more kinds can be used in combination.

The average particle size of the inorganic filler may be 50 nm or more, 100 nm or more, or 200 nm or more, and may be 10 μm or less, 5.0 μm or less, 3.0 μm or less, or 1.0 μm or less. The average particle size of the inorganic filler is preferably 100 nm to 10 μm or 50 nm to 5.0 μm, more preferably 100 nm to 3.0 μm, and still more preferably 200 nm to 1.0 μm. When the average particle size of the inorganic filler is in the above range, the surface roughness of the sheet can be reduced, and adhesiveness to base materials such as a polyimide film and copper foil can be enhanced.

As the average particle size of the inorganic filler, the value of a median size (d₅₀) at which the cumulative frequency of particle size in a volume cumulative particle size distribution is 50% is employed. The average particle size can be measured using a particle size distribution measurement device of a laser diffraction/scattering system.

The inorganic filler is preferably surface-treated, and is preferably one surface-treated with a coupling agent, and more preferably one surface-treated with a silane coupling agent. By the inorganic filler being surface-treated, not only can the dispersibility of the inorganic filler in the organic solvent be enhanced, but also the surface roughness of the surface of the sheet is reduced even more, and adhesiveness to base materials such as a polyimide film and copper foil can be enhanced.

Examples of the coupling agent include a silane coupling agent, a titanium coupling agent, an aluminum coupling agent, and the like. Examples of the silane coupling agent include methacrylic silane, acrylic silane, aminosilane, phenylaminosilane, imidazole silane, phenylsilane, vinylsilane, epoxy silane, and the like. For these, one kind can be used singly, or two or more kinds can be used in combination.

In the case where the resin composition contains an inorganic filler, the content amount may be 5 to 75 mass %, 5 to 50 mass %, 5 to 35 mass %, or 10 to 30 mass % with respect to the total amount of solid content (nonvolatile content) of the resin composition (100 mass %). When the content amount of the inorganic filler is 75 mass % or less, there is a tendency that a reduction in adhesiveness can be suppressed, and when the content amount is 5 mass % or more, there is a tendency that the effect of reducing the dielectric loss tangent and the effect of improving heat resistance are sufficiently obtained.

### <Cured Product>

The cured product of the present embodiment is one obtained by curing the resin composition of the present embodiment. Specifically, it can be obtained by subjecting the composition to heating treatment at about 150 to 250° C. for about 10 minutes to 3 hours.

The shape of the cured product of the present embodiment is not particularly limited; when the cured product is used for bonding of a base material, the cured product can be formed in a sheet shape having a film thickness of usually about 1 to 200 sm, preferably about 3 to 100 sm; thus, the film thickness can be adjusted according to the use, as appropriate.

### <Sheet>

The sheet of the present embodiment includes the resin composition of the present embodiment and a base material. The sheet of the present embodiment is obtained by, for example, applying the resin composition of the present embodiment to a base material (sheet base material) and performing drying. Examples of the base material include organic base materials such as polyimides, polyimide-silica hybrids, polyamides, polyethylene (PE), polypropylene (PP), polyethylene terephthalate (PET), polyethylene naphthalate (PEN), polymethyl methacrylate resin (PMMA), polystyrene resin (PSt), polycarbonate resin (PC), acrylonitrile-butadiene-styrene resin (ABS), and an aromatic compound-based polyester resin (what is called a liquid crystal polymer; “Vecstar”, manufactured by Kuraray Co., Ltd., or the like) obtained from ethylene terephthalate, phenol, phthalic acid, hydroxynaphthoic acid, or the like and parahydroxybenzoic acid; among these, polyimide films, particularly polyimide-silica hybrid films, are preferable from the viewpoint of heat resistance, dimensional stability, etc. As the base material, also glass, a metal such as iron, aluminum, alloy 42, or copper, or an inorganic base material such as ITO, silicon, or silicon carbide may be used. The thickness of the base material can be set according to the use, as appropriate.

### <Laminate>

The laminate of the present embodiment is obtained by thermocompression-bonding a base material to an adhesive surface of the sheet. As the base material, for example, organic base materials such as polyimides, polyimide-silica hybrids, polyamides, polyethylene (PE), polypropylene (PP), polyethylene terephthalate (PET), polyethylene naphthalate (PEN), polymethyl methacrylate resin (PMMA), polystyrene resin (PSt), polycarbonate resin (PC), acrylonitrile-butadiene-styrene resin (ABS), and an aromatic compound-based polyester resin (what is called a liquid crystal polymer; “Vecstar”, manufactured by Kuraray Co., Ltd., or the like) obtained from ethylene terephthalate, phenol, phthalic acid, hydroxynaphthoic acid, or the like and parahydroxybenzoic acid can be used. As the base material, also glass, a metal such as iron, aluminum, alloy 42, or copper, or an inorganic base material such as ITO, silicon, or silicon carbide may be used. The thickness of the base material can be set according to the use, as appropriate. The laminate may be one further subjected to heating treatment.

### <Printed Board and Printed Wiring Board>

The printed board of the present embodiment is one using the sheet or one using the laminate. The printed board of the present embodiment is obtained by, for example, bonding an adhesive surface of the sheet to the inorganic base material surface of the laminate. The printed board is preferably one using a polyimide film as an organic base material and metal foil (in particular, copper foil) as an inorganic base material. Then, the metal surface of the printed board is subjected to soft etching treatment to form a circuit, and the sheet is bonded and hot-pressed onto the circuit; thereby, a printed wiring board is obtained.

### EXAMPLES

The present disclosure will now be specifically described using Examples and Comparative Examples, but the present disclosure is not limited thereto.

### <Synthesis of Maleimide Resin>

### Synthesis Example 1

39.39 parts by mass of 9,9-bis(3,4-dicarboxyphenyl)fluorene dianhydride (trade name: “BPAF”, manufactured by JFE Chemical Corporation), 165.77 parts by mass of T-SOL 100 (trade name, an aromatic compound-based high-boiling-point solvent, manufactured by ENEOS Corporation), and 35.04 parts by mass of SOLMIX A-11 (trade name, an alcohol-based solvent, manufactured by Japan Alcohol Trading Co., Ltd.) were put into a 0.3 L or 1 L flask vessel equipped with a condenser, a nitrogen introduction tube, a thermocouple, and a stirrer. After the putting-in, the temperature was increased to 80° C., the condition was kept warm for 0.5 hours, and 43.07 parts by mass of a dimer diamine (DDA) (trade name: “PRIAMINE 1075”, manufactured by Croda Japan K.K.) was added dropwise. After the dropwise addition, 5.30 parts by mass of norbornanediamine (manufactured by Mitsui Fine Chemicals, INC Co., Ltd.) was added dropwise. After that, the condition was kept warm at 80° C. for about 0.25 to 1 hour. After the warm keeping, 2.20 parts by mass of a methanesulfonic acid aqueous solution (trade name: “Lutropur MSA”, manufactured by BASF SE) was added. After that, the temperature was increased to 160° C. After the temperature increase, 50.00 parts by mass of toluene (manufactured by Yamaichi Chemical Industries Co., Ltd.) was added, a dehydration ring closure reaction (a first dehydration ring closure reaction) was performed at 160° C. for 2 hours, the water and the alcohol in the reaction liquid were removed, and a polyimide resin of an intermediate was obtained. Subsequently, the obtained polyimide resin was cooled to 130° C., 8.42 parts by mass of maleic anhydride (manufactured by Fuso Chemical Co., Ltd.) was added, the temperature was increased to 160° C., a dehydration ring closure reaction (a second dehydration ring closure reaction) was performed at 160° C. for 4 hours, the water in the reaction liquid was removed, and a maleimide resin (bismaleimide resin) was obtained.

The obtained bismaleimide resin was put into a separating funnel, 500 parts by mass of pure water was put in, and the separating funnel was shaken and was allowed to stand still. After the aqueous layer and the organic layer were separated after the still standing, only the organic layer was collected. The collected organic layer was put into a 0.3 L glass vessel equipped with a condenser, a nitrogen introduction tube, a thermocouple, a stirrer, and a vacuum pump, the temperature was increased to 88 to 93° C., water was removed, then the temperature was increased to 100° C., and the solvent was partially removed for 0.5 hours in a state where the pressure was reduced from atmospheric pressure by 0.1 MPa; thus, a solution of a bismaleimide resin (A-1) as the (A) component was obtained.

### Synthesis Examples 2 to 4

Solutions of bismaleimide resins (A-2) to (A-4) were obtained in similar manners to Synthesis Example 1 except that the blending amounts of the components were changed as shown in Table 1. In Synthesis Example 2, as the solvent, pseudocumene and N-methyl-2-pyrrolidone were used in the amounts shown in Table 1 in place of T-SOL 100 of Synthesis Example 1.

### Synthesis Examples 5 to 7

Solutions of bismaleimide resins (A-5) to (A-7) were obtained in similar manners to Synthesis Example 1 except that 9,9-bis(3,4-dicarboxyphenyl)fluorene dianhydride (BPAF) was changed to 9,9-bis[4-(3,4-dicarboxyphenoxy)phenyl]fluorene dianhydride (trade name: “BPF-PA”, manufactured by FE Chemical Corporation) and the blending amounts of the components were changed as shown in Table 1.

### Synthesis Examples 8 and 9

Solutions of bismaleimide resins (A-8) and (A-9) were obtained in similar manners to Synthesis Example 1 except that 9,9-bis(3,4-dicarboxyphenyl)fluorene dianhydride (BPAF) was changed to 1,3,3a,4,5,9b-hexahydro-5-(tetrahydro-2,5-dioxo-3-furanyl)naphtho[1,2-C]furan-1,3-dione (trade name: “TDA-100”, manufactured by New Japan Chemical Co., Ltd.), norbornanediamine was changed to 9,9-bis[4-(4-aminophenoxy)phenyl]fluorene (trade name: “BPF-AN”, manufactured by JFE Chemical Corporation), and the blending amounts of the components were changed as shown in Table 1.

### Synthesis Examples 10 and 11

Solutions of bismaleimide resins (A-10) and (A-11) were obtained in similar manners to Synthesis Example 1 except that norbornanediamine was changed to 9,9-bis[4-(4-aminophenoxy)phenyl]fluorene (trade name: “BPF-AN”, manufactured by FE Chemical Corporation) and the blending amounts of the components were changed as shown in Table 1.

### Synthesis Examples 12 to 14

Solutions of bismaleimide resins (A-12) to (A-14) were obtained in similar manners to Synthesis Example 1 except that 9,9-bis(3,4-dicarboxyphenyl)fluorene dianhydride (BPAF) was changed to 9,9-bis[4-(3,4-dicarboxyphenoxy)phenyl]fluorene dianhydride (trade name: “BPF-PA”, manufactured by JFE Chemical Corporation), norbornanediamine was changed to 9,9-bis[4-(4-aminophenoxy)phenyl]fluorene (trade name: “BPF-AN”, manufactured by JFE Chemical Corporation), and the blending amounts of the components were changed as shown in Table 1.

### Synthesis Example 15

A solution of a bismaleimide resin (A-15) was obtained in a similar manner to Synthesis Example 1 except that 9,9-bis(3,4-dicarboxyphenyl)fluorene dianhydride (BPAF) was changed to 1,3,3a,4,5,9b-hexahydro-5-(tetrahydro-2,5-dioxo-3-furanyl)naphtho[1,2-C]furan-1,3-dione (trade name: “TDA-100”, manufactured by New Japan Chemical Co., Ltd.) and the blending amounts of the components were changed as shown in Table 1.

### Synthesis Example 16

A solution of a bismaleimide resin (A-16) was obtained in a similar manner to Synthesis Example 1 except that norbornanediamine was not used and the blending amounts of the components were changed as shown in Table 1.

### Synthesis Examples 17 to 19

The process up to the second dehydration ring closure reaction was performed in similar manners to Synthesis Example 1 except that the blending amounts of the components were changed as shown in Table 2, the water in the reaction liquid was removed, and a maleimide resin (bismaleimide resin) was obtained. As the solvent, N-methyl-2-pyrrolidone was used in the amount shown in Table 2 in place of SOLMIX A-1 of Synthesis Example 1. The obtained bismaleimide resin was added dropwise to a large amount of isopropanol and was precipitated, and then the precipitated resin was collected by suction filtration. The collected resin powder was cleaned with isopropanol several times, then holding was performed for 12 to 24 hours in a state where the temperature was increased to 60 to 90° C., and thereby isopropanol was removed; thus, purified powders of bismaleimide resins (A-17) to (A-19) were obtained.

### Synthesis Example 20

A solution of a bismaleimide resin (A-20) was obtained in a similar manner to Synthesis Example 1 except that 9,9-bis(3,4-dicarboxyphenyl)fluorene dianhydride (BPAF) was changed to 9,9-bis[4-(3,4-dicarboxyphenoxy)phenyl]fluorene dianhydride (trade name: “BPF-PA”, manufactured by JFE Chemical Corporation), norbornanediamine was changed to 9,9-bis(4-aminophenyl)fluorene (trade name: “BAFL”, manufactured by JFE Chemical Corporation), and the blending amounts of the components were changed as shown in Table 2.

### Synthesis Example 21

A powder of a bismaleimide resin (A-21) was obtained in a similar manner to Synthesis Examples 17 to 19 except that 3,3′,4,4′-biphenyltetracarboxylic dianhydride (BPDA) was used together with 9,9-bis(3,4-dicarboxyphenyl)fluorene dianhydride (BPAF) and the blending amounts of the components were changed as shown in Table 2.

### Synthesis Example 22

A powder of a bismaleimide resin (A-22) was obtained in a similar manner to Synthesis Examples 17 to 19 except that 9,9-bis(3,4-dicarboxyphenyl)fluorene dianhydride (BPAF) was changed to 9,9-bis[4-(3,4-dicarboxyphenoxy)phenyl]fluorene dianhydride (trade name: “BPF-PA”, manufactured by JFE Chemical Corporation), also 3,3′,4,4′-biphenyltetracarboxylic dianhydride (BPDA) was used as an acid anhydride, and the blending amounts of the components were changed as shown in Table 2.

### <Nonvolatile Content (NV)>

0.75 g±0.25 g of each of the solutions of the bismaleimide resins (A-1) to (A-16) and (A-20) and the powders of the bismaleimide resins (A-17) to (A-19), (A-21), and (A-22) was weighed out with a precision balance on a metal laboratory dish, and was then dried at 150° C. for 0.5 hours with a hot air dryer, and the nonvolatile content (NV) was calculated from the following formula. The results are shown in Tables 1 and 2.

NV (mass %)={(W3−W1)/W2}×100
W1: the mass (g) of the empty metal laboratory dish
W2: the mass (g) of the solution or the powder of the bismaleimide resin before drying
W3: the mass (g) of the metal laboratory dish+the bismaleimide resin after drying

### <Weight Average Molecular Weight (Mw) and Number Average Molecular Weight (Mn)>

The weight average molecular weight (Mw) and the number average molecular weight (Mn) of each of the bismaleimide resins (A-1) to (A-22) were measured by GPC (gel permeation chromatography). 50 μL of a sample in which the bismaleimide resin was dissolved in tetrahydrofuran (THF) such that the concentration was 3 mass % was injected into each of columns heated to 30° C. (GL-R420×1 column, GL-R430×1 column, and GL-R440×1 column (all manufactured by Hitachi High-Tech Fielding Corporation)); using THF as a developing solvent, measurement was performed under the condition of a flow velocity of 1.6 mL/min. An L-3350 RI detector (manufactured by Hitachi, Ltd.) was used as a detector, and Mw and Mn were found by conversion from the elution time with a molecular weight/elution time curve created using standard polystyrene (manufactured by Tosoh Corporation). The results are shown in Tables 1 and 2.

TABLE 1

| | | (A-1) | (A-2) | (A-3) | (A-4) | (A-5) | (A-6) | (A-7) | (A-8) | (A-9) |
|---|---|---|---|---|---|---|---|---|---|---|
| (a1) component | BPAF | 39.39 | 111.79 | 39.39 | 44.65 | — | — | — | — | — |
| | BPF-PA | — | — | — | — | 55.17 | 55.17 | 62.53 | — | — |
| | TDA-100 | — | — | — | — | — | — | — | 25.78 | 25.78 |
| | BPDA | — | — | — | — | — | — | — | — | — |
| (a2) component | DDA | 43.07 | 104.70 | 30.76 | 30.76 | 43.07 | 30.74 | 30.73 | 43.07 | 30.75 |
| | Norbornanediamine | 5.30 | 20.02 | 8.83 | 8.83 | 5.30 | 8.83 | 8.83 | — | — |
| | BAFL | — | — | — | — | — | — | — | — | — |
| | BPF-AN | — | — | — | — | — | — | — | 18.31 | 30.51 |
| (a3) component | Maleic anhydride | 8.42 | 23.90 | 8.42 | 5.05 | 8.42 | 8.42 | 5.05 | 8.42 | 8.42 |
| Acid catalyst | Methanesulfonic acid | 2.20 | 4.40 | 2.20 | 1.57 | 2.20 | 2.20 | 1.57 | 2.20 | 2.20 |
| | aqueous solution | | | | | | | | | |
| Solvent | T-SOL100 | 165.77 | — | 152.06 | 194.83 | 195.08 | 178.79 | 236.56 | 164.65 | 164.87 |
| | Pseudocumene | — | 250.10 | — | — | — | — | — | — | — |
| | SOLMIX A-11 | 35.04 | 107.40 | 32.69 | 40.93 | 41.04 | 38.16 | 48.52 | 35.45 | 35.69 |
| | NMP | — | 50.00 | — | — | — | — | — | — | — |
| | Toluene | 50.00 | 60.00 | 50.00 | 50.00 | 50.00 | 50.00 | 50.00 | 50.00 | 90.00 |

| | | | | | | | | | |
|---|---|---|---|---|---|---|---|---|---|
| Molar ratio of DDA/second diamine | 70/30 | 60/40 | 50/50 | 50/50 | 70/30 | 50/50 | 50/50 | 70/30 | 50/50 |
| Molar ratio of (a1) component/(a2) | 0.75 | 0.75 | 0.75 | 0.85 | 0.75 | 0.75 | 0.85 | 0.75 | 0.75 |
| component | | | | | | | | | |
| NV (mass %) | 56.0 | 57.0 | 47.2 | 47.0 | 49.7 | 55.6 | 55.6 | 54.7 | 46.0 |
| Acid value (mg KOH/g) | 4.1 | 2.3 | 2.4 | 2.1 | 3.1 | 2.9 | 1.7 | 3.5 | 3.5 |
| Mn | 4800 | 4400 | 4700 | 6600 | 6500 | 5900 | 8600 | 3400 | 3400 |
| Mw | 12300 | 9700 | 11200 | 18000 | 16000 | 13600 | 22500 | 9700 | 8800 |

| | | (A-10) | (A-11) | (A-12) | (A-13) | (A-14) | (A-15) | (A-16) |
|---|---|---|---|---|---|---|---|---|
| (a1) component | BPAF | 39.39 | 39.39 | — | — | — | — | 39.39 |
| | BPF-PA | — | — | 55.17 | 55.17 | 41.73 | — | — |
| | TDA-100 | — | — | — | — | — | 24.35 | — |
| | BPDA | — | — | — | — | — | — | — |
| (a2) component | DDA | 43.09 | 30.74 | 43.07 | 30.74 | 26.82 | 41.37 | 61.53 |
| | Norbornanediamine | — | — | — | — | — | 5.00 | — |
| | BAFL | — | — | — | — | — | — | — |
| | BPF-AN | 18.32 | 30.51 | 18.31 | 30.51 | 26.63 | — | — |
| (a3) component | Maleic anhydride | 8.42 | 8.42 | 8.42 | 8.42 | 10.29 | 7.96 | 8.42 |
| Acid catalyst | Methanesulfonic acid | 2.20 | 2.20 | 2.20 | 2.20 | 2.47 | 2.08 | 2.20 |
| | aqueous solution | | | | | | | |
| Solvent | T-SOL100 | 189.99 | 194.00 | 220.59 | 219.14 | 220.61 | 157.22 | 194.62 |
| | Pseudocumene | — | — | — | — | — | — | — |
| | SOLMIX A-11 | 40.04 | 40.01 | 46.48 | 45.34 | 44.92 | 29.68 | 40.46 |
| | NMP | — | — | — | — | — | — | — |
| | Toluene | 65.00 | 60.00 | 60.00 | 70.00 | 70.00 | 56.00 | 50.00 |

| | | | | | | | |
|---|---|---|---|---|---|---|---|
| Molar ratio of DDA/second diamine | 70/30 | 50/50 | 70/30 | 50/50 | 30/70 | 70/30 | 100/0 |
| Molar ratio of (a1) component/(a2) | 0.75 | 0.75 | 0.75 | 0.75 | 0.75 | 0.75 | 0.75 |
| component | | | | | | | |
| NV (mass %) | 58.9 | 49.5 | 54.0 | 49.7 | 35.2 | 58.8 | 64.0 |
| Acid value (mg KOH/g) | 3.6 | 3.0 | 2.5 | 2.3 | 4.3 | 5.5 | 1.8 |
| Mn | 4400 | 4800 | 5300 | 5500 | 6500 | 4300 | 6000 |
| Mw | 13100 | 12400 | 16100 | 15400 | 17600 | 10900 | 15500 |

TABLE 2

| | | (A-17) | (A-18) | (A-19) | (A-20) | (A-21) | (A-22) |
|---|---|---|---|---|---|---|---|
| (a1) component | BPAF | 41.25 | 78.38 | 48.20 | — | 22.35 | — |
| | BPF-PA | — | — | — | 34.71 | — | 28.89 |
| | TDA-100 | — | — | — | — | — | — |
| | BPDA | — | — | — | — | 14.34 | 13.24 |
| (a2) component | DDA | 19.34 | 28.99 | 16.06 | 19.33 | 20.94 | 19.40 |
| | Norbornanediamine | 12.95 | 19.43 | 10.79 | — | 14.04 | 12.97 |
| | BAFL | — | — | — | 12.55 | — | — |
| | BPF-AN | — | — | — | — | — | — |
| (a3) component | Maleic anhydride | 8.82 | 2.64 | 7.35 | 5.30 | 9.56 | 8.83 |
| Acid catalyst | Methanesulfonic acid | 2.30 | 0.61 | 1.92 | 1.38 | 2.48 | 2.30 |
| | aqueous solution | | | | | | |
| Solvent | T-SOL100 | 29.57 | 47.97 | 32.55 | 125.40 | 27.30 | 28.24 |
| | Pseudocumene | — | — | — | — | — | — |
| | SOLMIX A-11 | — | — | — | 26.25 | — | — |
| | NMP | 69.79 | 119.60 | 83.00 | — | 68.15 | 70.58 |
| | Toluene | 42.50 | 71.94 | 42.68 | 40.00 | 40.89 | 42.36 |

| | | | | | | |
|---|---|---|---|---|---|---|
| Molar ratio of DDA/second diamine | 30/70 | 30/70 | 30/70 | 50/50 | 30/70 | 30/70 |
| Molar ratio of (a1) component/(a2) | 0.75 | 0.95 | 0.75 | 0.75 | 0.75 | 0.75 |
| component | | | | | | |
| NV (mass %) | 96.9 | 96.9 | 96.9 | 46.9 | 97.0 | 97.0 |
| Acid value (mg KOH/g) | 9.6 | 3.8 | 9.6 | 2.97 | 10.6 | 9.7 |
| Mn | 3100 | 10900 | 3800 | 5500 | 4300 | 4300 |
| Mw | 6100 | 29000 | 7400 | 11900 | 15800 | 11500 |

### Examples 1 to 20 and Comparative Examples 1 and 2

### <Production of Resin Composition and Cured Sheet>

The components shown below were blended in the blending amounts (unit: parts by mass) shown in Tables 3 and 4, and resin compositions of Examples and Comparative Examples were prepared.

The blending amount of the (A) component shown in Tables 3 and 4 shows the blending amount including the solvent.

### (A) Component: Maleimide Resin

The solutions or powders of the bismaleimide resins (A-1) to (A-22) prepared in Synthesis Examples 1 to 22 above

### (B) Component: Polymerization Initiator

DCP (trade name: “PERCUMYL D”, dicumyl peroxide, manufactured by NOF Corporation)

Next, using an applicator, the resin composition was applied onto copper foil (trade name: “FZ-WS-18”, manufactured by Furukawa Electric Co., Ltd.) such that the thickness became 100 μm after drying, and drying treatment was performed at 130° C. for 30 minutes with a dryer. Subsequently, curing treatment at 200° C. for 1 hour was performed with a dryer. After the curing, cooling was performed to room temperature, then the copper foil was removed by etching with an ammonium persulfate aqueous solution, and drying was performed at 110° C. for 30 minutes; thus, a cured sheet was produced.

### [Measurement of Elastic Modulus and Tg]

A test piece having a sample size of 20 mm×10 mm was produced using the cured sheet. Using this test piece, the elastic modulus and Tg (the tan δ peak) at 20° C. were measured with a dynamic viscoelasticity measurement device (trade name: “DMS 6100”, manufactured by SII NanoTechnology Inc.) under the conditions of a frequency of 1 Hz, measurement temperatures of −40° C. to 220° C., and a rate of temperature increase of 10° C./min. The results are shown in Tables 3 and 4.

### [Evaluation of Dielectric Characteristics]

A test piece having a sample size of 50 mm×100 mm was produced using the cured sheet. Using this test piece, the relative permittivity (Dk) and the dielectric loss tangent (Df) at 10 GHz were measured with an SPDR dielectric resonator (manufactured by Agilent Technologies Japan Ltd.). The results are shown in Tables 3 and 4.

### [Coefficient of Linear Expansion (CTE)]

A test piece having a size of 18 mm×4 mm was produced from the cured sheet. Using this test piece, the coefficient of linear expansion (CTE) was measured using a thermomechanical analyzer (trade name: “TMA-60”, manufactured by Shimadzu Corporation). The measurement mode was set to a tensile mode, the measurement load was to 10 mN, the measurement atmosphere was to a nitrogen atmosphere, the rate of temperature increase was to 5° C./min, and the measurement temperature range was to −50 to 250° C.; the measurement result of the 2nd run at −20 to 40° C. was taken as the CTE. The results are shown in Tables 3 and 4.

TABLE 3

| | | Examples | | | | | | | | |
|---|---|---|---|---|---|---|---|---|---|---|
| | | 1 | 2 | 3 | 4 | 5 | 6 | 7 | 8 | 9 |
| Maleimide | (A-1) | 100 | — | — | — | — | — | — | — | — |
| resin (A) | (A-2) | — | 100 | — | — | — | — | — | — | — |
| | (A-3) | — | — | 100 | — | — | — | — | — | — |
| | (A-4) | — | — | — | 100 | — | — | — | — | — |
| | (A-5) | — | — | — | — | 100 | — | — | — | — |
| | (A-6) | — | — | — | — | — | 100 | — | — | — |
| | (A-7) | — | — | — | — | — | — | 100 | — | — |
| | (A-8) | — | — | — | — | — | — | — | 100 | — |
| | (A-9) | — | — | — | — | — | — | — | — | 100 |
| | (A-10) | — | — | — | — | — | — | — | — | — |
| | (A-11) | — | — | — | — | — | — | — | — | — |
| | (A-12) | — | — | — | — | — | — | — | — | — |
| | (A-13) | — | — | — | — | — | — | — | — | — |
| | (A-14) | — | — | — | — | — | — | — | — | — |
| | (A-15) | — | — | — | — | — | — | — | — | — |
| | (A-16) | — | — | — | — | — | — | — | — | — |
| Polymerization | DCP | 0.56 | 0.57 | 0.47 | 0.47 | 0.50 | 0.56 | 0.56 | 0.55 | 0.46 |
| initiator (B) | | | | | | | | | | |
| Evaluation | Elastic modulus | 1.7 | 1.5 | 2.2 | 2.0 | 1.6 | 2.2 | 2.6 | 2.2 | 2.0 |
| items | (GPa) | | | | | | | | | |
| | Tg (° C.) | 100 | 133 | 136 | 138 | 94 | 116 | 117 | 96 | 153 |
| | CTE (ppm/° C.) | 122 | 93 | 88 | 88 | 99 | 84 | 84 | 122 | 102 |
| | Dk | 2.34 | 2.41 | 2.53 | 2.61 | 2.58 | 2.76 | 2.58 | 2.48 | 2.74 |
| | Df | 0.0023 | 0.0017 | 0.0027 | 0.0026 | 0.0024 | 0.0024 | 0.0025 | 0.0024 | 0.0026 |

| | | Examples | | | | | Comparative Examples | |
|---|---|---|---|---|---|---|---|---|
| | | 10 | 11 | 12 | 13 | 14 | 1 | 2 |
| Maleimide | (A-1) | — | — | — | — | — | — | — |
| resin (A) | (A-2) | — | — | — | — | — | — | — |
| | (A-3) | — | — | — | — | — | — | — |
| | (A-4) | — | — | — | — | — | — | — |
| | (A-5) | — | — | — | — | — | — | — |
| | (A-6) | — | — | — | — | — | — | — |
| | (A-7) | — | — | — | — | — | — | — |
| | (A-8) | — | — | — | — | — | — | — |
| | (A-9) | — | — | — | — | — | — | — |
| | (A-10) | 100 | — | — | — | — | — | — |
| | (A-11) | — | 100 | — | — | — | — | — |
| | (A-12) | — | — | 100 | — | — | — | — |
| | (A-13) | — | — | — | 100 | — | — | — |
| | (A-14) | — | — | — | — | 100 | — | — |
| | (A-15) | — | — | — | — | — | 100 | — |
| | (A-16) | — | — | — | — | — | — | 100 |
| Polymerization | DCP | 0.59 | 0.50 | 0.54 | 0.50 | 0.35 | 0.59 | 0.64 |
| initiator (B) | | | | | | | | |
| Evaluation | Elastic modulus | 1.8 | 2.2 | 1.8 | 1.7 | 2.5 | 1.1 | 1.0 |
| items | (GPa) | | | | | | | |
| | Tg (° C.) | 126 | 176 | 95 | 138 | 200 | 71 | 66 |
| | CTE (ppm/° C.) | 90 | 71 | 87 | 71 | 64 | 149 | 116 |
| | Dk | 2.48 | 2.60 | 2.43 | 2.36 | 2.64 | 2.34 | 2.23 |
| | Df | 0.0021 | 0.0024 | 0.0019 | 0.0021 | 0.0023 | 0.0015 | 0.0023 |

TABLE 4

| | | Examples | | | | | |
|---|---|---|---|---|---|---|---|
| | | 15 | 16 | 17 | 18 | 19 | 20 |
| Maleimide | (A-17) | 100 | — | — | — | — | — |
| resin (A) | (A-18) | — | 100 | — | — | — | — |
| | (A-19) | — | — | 100 | — | — | — |
| | (A-20) | — | — | — | 100 | — | — |
| | (A-21) | — | — | — | — | 100 | — |
| | (A-22) | — | — | — | — | — | 100 |
| Polymerization | DCP | 0.40 | 0.40 | 0.40 | 0.47 | 0.40 | 0.40 |
| initiator (B) | | | | | | | |
| Evaluation | Elastic modulus | 2.9 | 2.7 | 2.6 | 2.2 | 2.0 | 2.3 |
| items | (GPa) | | | | | | |
| | Tg (° C.) | 192 | 195 | 157 | 213 | 165 | 155 |
| | CTE (ppm/° C.) | 71 | 78 | 65 | 84 | 78 | 72 |
| | Dk | 2.69 | 2.86 | 2.69 | 2.63 | 2.57 | 2.67 |
| | Df | 0.0026 | 0.0023 | 0.0028 | 0.0030 | 0.0029 | 0.0028 |

As is clear from the results shown in Tables 3 and 4, it has been found that the resin composition using the maleimide resin of each of the Examples has, as characteristics of the cured product, excellent low dielectric characteristics (a low Dk and a low Df), a high elastic modulus, a high Tg, and a low CTE. Thus, it is expected that, by using the maleimide resin of the present disclosure, characteristics of laminate boards such as printed boards and sealing materials for electronic components of semiconductors, etc. will be dramatically improved.

1. A maleimide resin obtained by reacting a tetracarboxylic dianhydride (a1), an amine (a2), and maleic anhydride (a3),
wherein the amine (a2) contains a dimer diamine and a second amine other than the dimer diamine, and
at least one of the tetracarboxylic dianhydride (a1) and the amine (a2) contains a compound having a fluorene skeleton.

2. The maleimide resin according claim 1, wherein the tetracarboxylic dianhydride (a1) contains at least one of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 9,9-bis[4-(3,4-dicarboxyphenoxy)phenyl]fluorene dianhydride, and 3,3′,4,4′-biphenyltetracarboxylic dianhydride.

3. The maleimide resin according to claim 1, wherein the second amine contains at least one of norbornanediamine, 9,9-bis[4-(4-aminophenoxy)phenyl]fluorene, and 9,9-bis(4-aminophenyl)fluorene.

4. The maleimide resin according to claim 1, wherein the dimer diamine contains at least one of compounds represented by General Formula (1) below and compounds represented by General Formula (2) below, 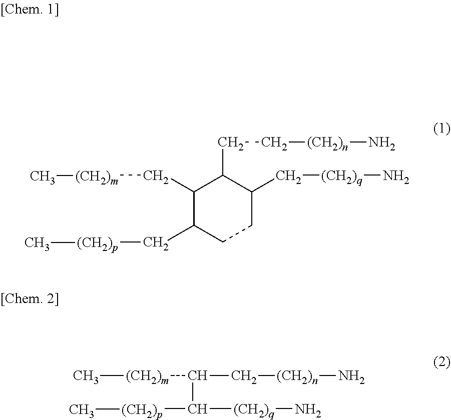
wherein m, n, p, and q each represent an integer of 1 or more selected such that m+n=6 to 17 and p+q=8 to 19, and a bond indicated by a broken line represents a carbon-carbon single bond or a carbon-carbon double bond, provided that, when the bond indicated by the broken line is a carbon-carbon double bond, each of Formulae (1) and (2) has a structure in which a number of hydrogen atoms bonded to each carbon atom forming the carbon-carbon double bond is a number obtained by subtracting 1 from a number shown in a respective one of Formulae (1) and (2).

5. The maleimide resin according to claim 1, wherein a weight average molecular weight is 3000 to 30000.

6. The maleimide resin according to claim 1, obtained by reacting 0.30 to 1.00 mol of the tetracarboxylic dianhydride (a1) with 1 mol of the amine (a2).

7. A resin composition comprising the maleimide resin (A) according to claim 1.

8. The resin composition according to claim 7, further comprising a polymerization initiator (B).

9. A cured product of the resin composition according to claim 7.

10. A sheet comprising: the resin composition according to claim 7; and a base material.

11. The sheet according to claim 10, wherein the base material is an organic base material.

12. The sheet according to claim 10, wherein the base material is an inorganic base material.

13. A laminate obtained by thermocompression-bonding a base material to an adhesive surface of the sheet according to claim 10.

14. A printed wiring board obtained by using the sheet according to claim 10.

15. A printed wiring board obtained by using the laminate according to claim 13.
